(19) United States
(12) Patent Application Publication
(10) Pub. No.: US 2020/0144322 A1
(43) Pub. Date: May 7, 2020

(54) IMAGING APPARATUS AND METHOD OF MANUFACTURING IMAGING APPARATUS

(71) Applicant: SONY SEMICONDUCTOR SOLUTIONS CORPORATION, Kanagawa (JP)

(72) Inventors: Keishi INOUE, Kumamoto (JP); Eiichiro KANDA, Kumamoto (JP)

(73) Assignee: SONY SEMICONDUCTOR SOLUTIONS CORPORATION, Kanagawa (JP)

(21) Appl. No.: 16/625,245

(22) PCT Filed: Jun. 22, 2018
(86) PCT No.: PCT/JP2018/023740

§ 371 Date: Dec. 20, 2019

(30) Foreign Application Priority Data
Jul. 18, 2017 (JP) 2017-139111

(51) Int. Cl. H01L 27/146; H01L 23/00; H04N 5/378; H04N 5/369

(52) U.S. Cl. CPC H01L 27/14636; H01L 2224/48463; H01L 27/14634; H01L 27/14683; H01L 24/03; H01L 27/14645; H04N 5/378; H04N 5/379; H01L 2224/0557; H01L 2224/05567; H01L 2224/04042; H01L 27/14627; H01L 27/14621; H01L 2224/03614; H01L 27/1464; H01L 2224/05624; H01L 2224/48624; H01L 24/48; H01L 24/05

(57) ABSTRACT

A bonding pad formed to a desired thickness is arranged close to a surface of an image sensor. An imaging apparatus includes a semiconductor substrate, a wiring layer, and a signal transmission section. On the semiconductor substrate, a photoelectric conversion section for generating an image signal corresponding to emitted light is formed. The wiring section is formed by having an insulation layer and a wiring layer stacked one on top of the other. The signal transmission section is formed between a recessed section formed on a surface different from the light-receiving surface of the semiconductor substrate on the one hand and the wiring section on the other hand, the signal transmission section being arranged partially in the recessed section. The signal transmission section transmits an image signal transmitted by the wiring layer through an opening formed from the light-receiving surface of the semiconductor substrate toward the recessed section.

### TECHNICAL FIELD

The present technology relates to an imaging apparatus and a method of manufacturing the imaging apparatus. More particularly, the technology relates to an imaging apparatus having bonding pads and a method of manufacturing the same.

### BACKGROUND ART

Heretofore, back-illuminated solid-state image sensors use bonding pads to allow wire bonding for outputting an image signal generated therein to the outside. Here, wire bonding is a method of electrically connecting bonding wires, which are constituted by gold (Au), for example, to bonding pads by welding. For example, a bonding wire is threaded through an instrument called a capillary. The tip of the bonding wire is formed into a spherical shape by electric discharge heating. The capillary is then used to perform wire bonding in which the tip of the bonding wire is heat- and pressure-bonded to a bonding pad. At this time, the bonding pad needs to be arranged close to the surface of the solid-state image sensor in order to prevent interference between the capillary and the solid-state image sensor. When the solid-state image sensor is inspected prior to wire bonding, the bonding pad may be used as an inspection pad. Specifically, the solid-state image sensor is inspected by bringing an inspection probe into contact with the bonding pad to measure image signals. At this point, the bonding pad is also arranged close to the surface of the solid-state image sensor to facilitate contact of the inspection probe with the bonding pad.

What is typically used here as the solid-state image sensor is an image sensor including a silicon layer that has a pixel section for performing photoelectric conversion of incident light, multiple interlayer dielectric films and copper wiring layers arranged adjacent to the silicon layer, and bonding pads constituted by aluminum (Al), for example. In this solid-state image sensor, the bonding pads are formed in the same position as the copper wires in the copper wiring layer closest to the silicon layer. The solid-state image sensor further has openings formed on the bonding pads in a manner penetrating the silicon layer and the interlayer dielectric films arranged adjacent to the silicon layer. Wire bonding is carried out through the openings to connect the bonding wires (e.g., see PTL1).

In this solid-state image sensor, the bonding pads are arranged in the same position as the copper wires in the copper wire layer closest to the silicon layer. This enables the bonding pads to be formed relatively close to the surface of the solid-state image sensor. On the other hand, the bonding pads are formed to a film thickness substantially the same as that of the above-mentioned copper wires.

### CITATION LIST

### Patent Literature

### [PTL 1]

Japanese Patent Laid-Open No. 2010-287638

### SUMMARY

### Technical Problem

At the time of bonding, the bonding pad being heated reacts with the bonding wire to turn into an alloy. Thus, in order to improve the connection strength of the bonding pad, it is necessary to form the bonding pad to a thickness that takes into account the amount of the bonding pad portion changing into the alloy. According to the above-described existing technology, however, the bonding pad is formed to substantially the same thickness as the copper wiring and is thus insufficient in thickness.

The present technology has been devised in view of the above problem. An object of the technology is therefore to form bonding pads to a desired thickness while arranging them close to the surface of the image sensor.

### Solution to Problem

The present technology is aimed at solving the above problem. According to a first aspect of the present technology, there is provided an imaging apparatus including: a semiconductor substrate on which is formed a photoelectric conversion section configured to generate an image signal corresponding to emitted light; a wiring section configured to have an insulation layer and a wiring layer stacked one on top of the other on a surface different from a light-receiving surface of the semiconductor substrate to which the light is emitted, the wiring layer transmitting the generated image signal; and a signal transmission section configured to be formed between a recessed section formed on the surface different from the light-receiving surface of the semiconductor substrate and the wiring section, the signal transmission section being further arranged partially in the recessed section, and further transmitting the image signal transmitted by the wiring layer through an opening formed from the light-receiving surface of the semiconductor substrate toward the recessed section. This provides an effect of allowing the signal transmission section embedded between the semiconductor substrate and the wiring section to transmit the image signal through the opening formed in the semiconductor substrate. What is envisaged is an increase in the size of the signal transmission section leading to regions including the semiconductor substrate and the wiring layer formed thereon.

Also according to the first aspect of the present technology, the imaging apparatus may further include an incident light transmission section configured to be arranged adjacent to the light-receiving surface and to transmit the emitted light to the photoelectric conversion section. The signal transmission section may transmit the image signal through the opening formed after fabrication of the incident light transmission section. This provides an effect of forming the incident light transmission section before fabrication of the opening leading to the signal transmission section. What is envisaged is simplified fabrication of the incident light transmission section.

Also according to the first aspect of the present technology, the signal transmission section may be configured with a pad. This provides an effect of allowing the image signal to be transmitted from the signal transmission configured with the pad through the opening.

Also according to the first aspect of the present technology, the imaging apparatus may further include a via plug configured to be arranged between the wiring layer and the signal transmission section and to transmit the image signal. This provides an effect of allowing the image signal to be transmitted from the wiring layer to the signal transmission section by way of the via plug.

Also according to the first aspect of the present technology, the imaging apparatus may further include: a second semiconductor substrate on which is formed a processing circuit configured to process an image signal transmitted by the wiring layer; a second wiring section configured to have a second insulation layer and a second wiring layer stacked one on top of the other on the second semiconductor substrate, the second wiring layer transmitting the processed image signal; and a second signal transmission section configured to transmit to the signal transmission section the processed image signal transmitted by the second wiring layer. The signal transmission section may transmit an image signal processed by the processing circuit and transmitted by the second signal transmission section. This provides an effect of allowing the image signal generated by the semiconductor substrate and processed by the processing circuit of the second semiconductor substrate to be transmitted to the signal transmission section via the second signal transmission section.

Also according to the first aspect of the present technology, the second signal transmission section may be configured with a pad arranged in the wiring section and with a pad arranged in the second wiring section. This provides an effect of allowing the second signal transmission section configured with two pads to transmit the image signal.

Also according to the first aspect of the present technology, the second signal transmission section may be configured with a via plug arranged in a manner penetrating the wiring section and the semiconductor substrate. This provides an effect of allowing the second signal transmission section configured with the via plug to transmit the image signal.

According to a second aspect of the present technology, there is provided a method of manufacturing an imaging apparatus, the method including the steps of: forming a signal transmission section partially in a recessed section formed on a surface different from a light-receiving surface of a semiconductor substrate on which is formed a photoelectric conversion section for generating an image signal corresponding to light emitted to the light-receiving surface, the signal transmission section being configured to transmit the image signal; forming a wiring section with a wiring layer adjacent to the surface different from the light-receiving surface of the semiconductor substrate and adjacent to the signal transmission section, the wiring layer being configured to transmit the image signal generated by the photoelectric conversion section to the signal transmission section; and forming an opening from the light-receiving surface of the semiconductor substrate toward the recessed section, the opening being configured to permit signal transmission from the signal transmission section. This provides an effect of allowing the image signal to be transmitted from the signal transmission section embedded between the semiconductor substrate and the wiring section through the opening formed in the semiconductor substrate. What is envisaged is an increase in the size of the signal transmission section leading to regions including the semiconductor substrate and the wiring layer formed thereon.

### Advantageous Effect of Invention

The present technology provides an advantageous effect of forming the bonding pads to a desired thickness while arranging them close to the surface of the image sensor.

### BRIEF DESCRIPTION OF DRAWINGS

FIG. 1 is a view depicting an example of a configuration of an imaging apparatus according to an embodiment of the present technology.

FIG. 2 is a view depicting an example of a configuration of a pixel circuit according to an embodiment of the present technology.

FIG. 3 is a view depicting an example of a configuration of an image sensor according to a first embodiment of the present technology.

FIG. 4 is a view depicting an exemplary method of manufacturing the image sensor according to the first embodiment of the present technology.

FIG. 5 is another view depicting the exemplary method of manufacturing the image sensor according to the first embodiment of the present technology.

FIG. 6 is another view depicting the exemplary method of manufacturing the image sensor according to the first embodiment of the present technology.

FIG. 7 is another view depicting the exemplary method of manufacturing the image sensor according to the first embodiment of the present technology.

FIG. 8 is a view depicting an exemplary method of manufacturing a signal transmission section according to the first embodiment of the present technology.

FIG. 9 is another view depicting another exemplary method of manufacturing the signal transmission section according to the first embodiment of the present technology.

FIG. 10 is a view depicting an example of the configuration of an image sensor according to a second embodiment of the present technology.

FIG. 11 is a view depicting an example of the configuration of an image sensor according to a third embodiment of the present technology.

FIG. 12 is a view depicting an example of the configuration of an imaging apparatus according to a fourth embodiment of the present technology.

FIG. 13 is a view depicting an example of the configuration of an imaging apparatus according to a fifth embodiment of the present technology.

FIG. 14 is a view depicting an example of the configuration of a via plug according to the fifth embodiment of the present technology.

FIG. 15 is a view depicting an example of the configuration of an imaging apparatus according to a modification of the fifth embodiment of the present technology.

FIG. 16 is a view depicting an example of the configuration of a via plug according to a modification of the fifth embodiment of the present technology.

### DESCRIPTION OF EMBODIMENTS

Some embodiments for implementing the present technology (referred to as the embodiments hereunder) are described below with reference to the accompanying drawings. Throughout the drawings, like or corresponding parts are designated by like or corresponding reference characters. It is to be noted that the drawings are only schematics and that the sizes and proportions of the parts depicted therein may not coincide with what actually occurs. Obviously, different drawings may include differences in size or proportion of the same parts. The description will be given under the following headings:

1. First Embodiment

2. Second Embodiment

3. Third Embodiment

4. Fourth Embodiment

5. Fifth Embodiment

### 1. First Embodiment

[Configuration of the Imaging Apparatus]

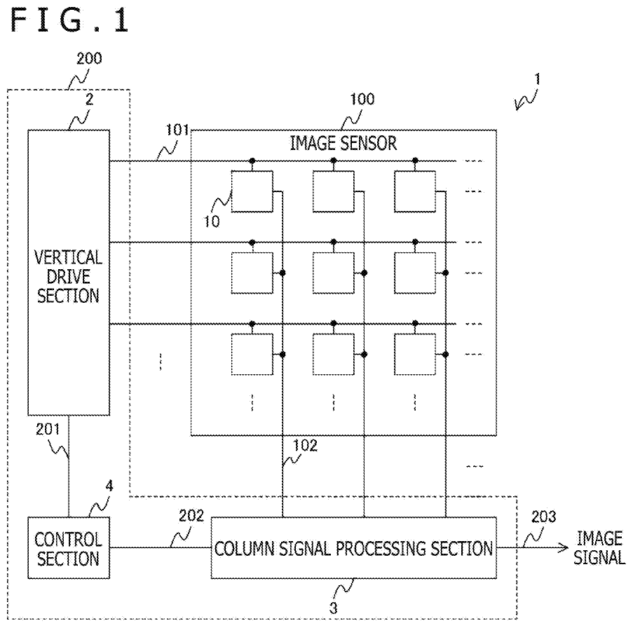

FIG. 1 is a view depicting an example of a configuration of an imaging apparatus according to an embodiment of the present technology. An imaging apparatus 1 in FIG. 1 includes an image sensor 100, a vertical drive section 2, a column signal processing section 3, and a control section 4.

The image sensor 100 is configured with pixels 10 arranged in a two-dimensional grid pattern. Here, the pixels 10 generate image signals corresponding to light from a subject. Each pixel 10 includes a photoelectric conversion section that generates electric charges corresponding to emitted light and a pixel circuit that generates an image signal based on the electric charges generated by the photoelectric conversion section. The configuration of the pixels 10 will be discussed later in detail.

Further, the image sensor 100 has signal lines 101 and 102 arranged in an XY matrix pattern, each of the signal lines being wired to multiple pixels 10. Here, the signal lines 101 transmitting control signals to control the pixel circuits of the pixels 10 are each arranged corresponding to each row of pixels 10 in the image sensor 100. Each signal line 101 is wired in common to one row of multiple pixels 10. The signal lines 102, which transmit pixel signals generated by the pixel circuits of the pixels 10, are each arranged corresponding to each column of pixels 10. Each signal line 102 is wired in common to one column of multiple pixels 10.

The vertical drive section 2 generating control signals for the pixels 10 outputs the generated signals via the signal lines 101. The vertical drive section 2 generates and outputs a different control signal to each of the rows of pixels 10 arranged in the image sensor 100.

The column signal processing section 3 processing image signals generated by the pixels 10 outputs the processed image signals. The processing by the column signal processing section 3 corresponds to an analog-to-digital conversion process, for example, of converting an analog image signal generated by each pixel 10 into a digital image signal. The images signals output from the column signal processing section 3 correspond to output signals of the imaging apparatus 1. Incidentally, the column signal processing section 3 is an example of the processing circuit described in the appended claims.

The control section 4 controls the vertical drive section 2 and the column signal processing section 3. The control section 4 performs control by generating and outputting control signals to the vertical drive section 2 and to the column signal processing section 3.

Note that the vertical drive section 2, column signal processing section 3, and control section 4 constitute a peripheral circuit chip 200. That is, the vertical drive section 2, column signal processing section 3, and control section 4 are formed in a single semiconductor chip. Similarly, the image sensor 100 is also formed in a single semiconductor chip. The imaging apparatus 1 is thus configured with two semiconductor chips of the image sensor 100 and of the peripheral circuit chip 200. It is to be noted that this example is not limitative of how the imaging apparatus 1 is configured. For example, the vertical drive section 2 and the image sensor 100 may be formed in one semiconductor chip.

[Configuration of the Pixel Circuit]

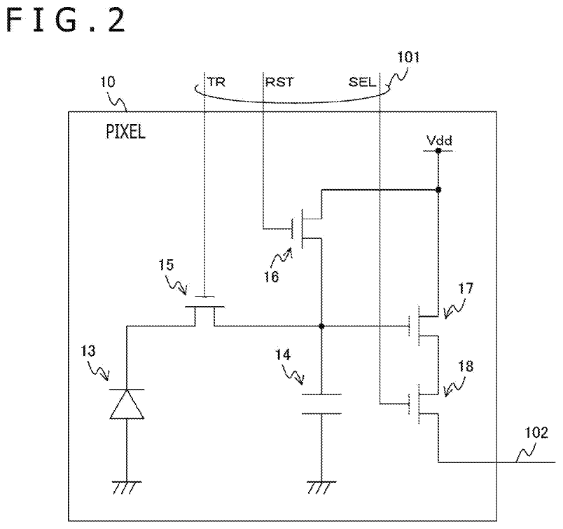

FIG. 2 is a view depicting an example of a configuration of a pixel circuit according to an embodiment of the present technology. The pixel 10 in FIG. 2 includes a photoelectric conversion section 13, a charge retention section 14, and MOS transistors 15 to 18.

The anode of the photoelectric conversion section 13 is grounded. The cathode of the photoelectric conversion section 13 is connected to the source of the MOS transistor 15. The drain of the MOS transistor 15 is connected to the source of the MOS transistor 16, to the gate of the MOS transistor 17, and to one end of the charge retention section 14. The other end of the charge retention section 14 is grounded. The drain of the MOS transistor 16 and that of the MOS transistor 17 are connected in common to a power supply line Vdd. The source of the MOS transistor 17 is connected to the drain of the MOS transistor 18. The source of the MOS transistor 18 is connected to a signal line 102. The gates of the MOS transistors 15, 16, and 18 are connected to a transfer signal line TR, to a reset signal line RST, and to a selection signal line SEL, respectively. The transfer signal line TR, reset signal line RST, and selection signal line SEL constitute a signal line 101.

The photoelectric conversion section 13 generates electric charges corresponding to the emitted light as mentioned above. A photodiode may be used as the photoelectric conversion section 13. The charge retention section 14 and the MOS transistors 15 to 18 constitute a pixel circuit.

The MOS transistor 15 is a transistor that transfers the electric charges generated by photoelectric conversion of the photoelectric conversion section 13 to the charge retention section 14. The transfer of electric charges by the MOS transistor 15 is controlled by signals transmitted via the signal transfer line TR. The charge retention section 14 is a capacitor that retains the electric charges transferred by the MOS transistor 15. The MOS transistor 17 is a transistor that generates a signal based on the electric charges retained in the charge retention section 14. The MOS transistor 18 is a transistor that outputs the signal generated by the MOS transistor 17 onto the signal line 102 as an image signal. The MOS transistor 18 is controlled by signals transmitted over the selection signal line SEL. The MOS transistor 16 is a transistor that resets the charge retention section 14 by discharging the electric charges retained therein onto the power supply line Vdd. The resetting by the MOS transistor 16, controlled by signals transmitted over the reset signal line RST, is executed before the MOS transistor 15 transfers the electric charges. In this manner, the pixel circuit converts the electric charges generated by the photoelectric conversion section (photoelectric conversion section 13) into the pixel signal.

[Configuration of the Image Sensor]

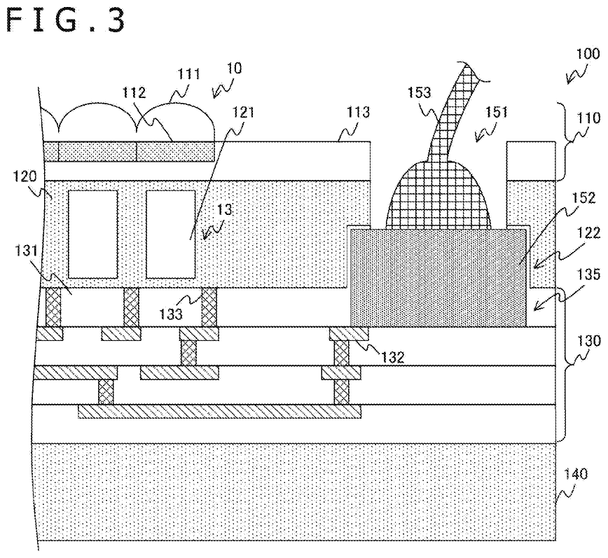

FIG. 3 is a view depicting an example of the configuration of an image sensor according to a first embodiment of the present technology. The image sensor 100 in FIG. 3 includes an incident light transmission section 110, a semiconductor substrate 120, a wiring section 130, a support substrate 140, and a pad 152.

The incident light transmission section 110 transmits the light incident on the image sensor 100 to the photoelectric conversion section 13 in the semiconductor substrate 120. The incident light transmission section 110 includes an on-chip lens 111 and a color filter 112. The on-chip lens 111 is a lens that focuses incident light onto the photoelectric conversion section 13. The color filter 112 is an optical filter that transmits light of a predetermined wavelength out of the light focused by the on-chip lens 111. The color filter 112 and the on-chip lens 111 are formed, in that order, on the surface of a protective film 113 fabricated on the semiconductor substrate 120.

The semiconductor substrate 120 is a semiconductor substrate on which the photoelectric conversion section 13 and semiconductor parts of the pixel circuit in the pixel 10 are formed. In FIG. 3, the semiconductor substrate 120 is configured as a P-type well region. An N-type semiconductor region 121 constituting the photoelectric conversion section 13 is formed in the well region. The N-type semiconductor region 121 forms a PN junction on a boundary with the surrounding well region. The light incident on the region of the PN junction causes photoelectric conversion. The electric charges generated by photoelectric conversion are stored in the N-type semiconductor region 121 before being converted to an electric signal by the pixel circuit (not depicted) and output as the image signal of the pixel 10.

The wiring section 130 is configured with a wiring layer 132 that transmits signals of the semiconductor substrate 120 and an insulation layer 131 that insulates the wiring layer 132. Moreover, the wiring layer 132 constitutes the signal lines 101 and 102 in FIG. 1. The signals transmitted by the wiring layer 132 correspond to the pixel signal generated by the pixel 10 and the control signal for the pixel circuit in the pixel 10. The wiring section 130 in FIG. 3 is an example of multilayer wiring with the wiring layer 132 and the insulation layer 131 stacked alternately in multiple layers. Via plugs 133 provide connection between the pixel circuits and the wiring layer 132 on the semiconductor substrate 120. Specifically, the via plugs 133 provide connection between the wiring layer 132 on the one hand, and the drain and source regions of those MOS transistors in the pixel circuits that are formed in a diffusion layer of the semiconductor substrate 120 and the gate electrodes formed on the surface of the semiconductor substrate 120 with an oxide film formed therebetween on the other hand. The via plugs 133 are also used to connect the wiring layers 132 with each other.

The support substrate 140 supports the semiconductor substrate 120, wiring section 130, and incident light transmission section 110. The support substrate 140 is configured using a semiconductor substrate, for example. In a step of manufacturing the image sensor 100, the support substrate 140 is bonded to the wiring section 130. Thereafter, the support substrate 140 supports and reinforces the semiconductor substrate 120 in a step of polishing the semiconductor substrate 120.

The pad 152, arranged between the semiconductor substrate 120 and the wiring section 130, transmits pixel signals and control signals transmitted by the wiring layer 132. The pad 152 is partially located in a recessed section 122 formed in the semiconductor substrate 120. The pad 152 is further connected with the wiring layer 132. The image signal sent by the wiring layer 132 is transmitted out of the image sensor 100 via an opening 151 formed in the semiconductor substrate 120. Specifically, the pad 152 is formed between the recessed section 122 formed in the semiconductor substrate 120 on the one hand, and a recessed section 135 of the insulation layer 131 adjacent to the semiconductor substrate 120 on the other hand. This formation provides the shortest-path connection between the pad 152 and the closest wiring layer 132 to the semiconductor substrate 120. The pad 152 further transmits the control signal for the pixel 10 that is input from outside the image sensor 100. In the image sensor 100 in FIG. 3, multiple pads 152 are arranged around the chip constituting the image sensor 100, for example. This arrangement allows multiple image signals and control signals to be exchanged between this chip and the peripheral circuit chip 200.

The pad 152 in FIG. 3 is used as a bonding pad to which a bonding wire 153 is connected. The pad 152 may be configured using Al and an Au wire may be used for the bonding wire. At the time of bonding, an alloy of Au and Al is formed to connect the pad 152 electrically with the bonding wire 153. Formation of the alloy reduces the film thickness of the pad 152. Also, at the time of bonding, the bonding wire is heat- and pressure-bonded to the pad 152 by the capillary. This requires that the pad 152 be provided with mechanical strength. For this reason, the pad 152 is formed to a relatively large film thickness. By contrast, the insulation layer 131 is formed to a film thickness required for interlayer insulation, the film thickness being smaller than that of the pad 152. In view of this, the recessed section 122 is formed in the semiconductor substrate 120 to accommodate that part of the pad 152 which exceeds the film thickness of the insulation layer 131. The pad 152 of a desired thickness is thus arranged without incurring an increase in the film thickness of the insulation layer 131.

With the pad 152 arranged in the recessed section 122 formed in the semiconductor substrate 120, the pad 152 is bonded through the opening 151 formed on the side of the light-receiving surface of the image sensor 100. As a result of this, that surface of the pad 152 to be bonded is located close to the light-receiving surface, which is the surface of the image sensor 100. This permits easy bonding because interference between the capillary and the image sensor 100 is prevented. Incidentally, the connection strength of bonding is evaluated in terms of ball shear strength. Here, ball shear strength refers to the shear strength of the bonded part after connection. The strength is measured by destroying (shearing) the connection section using a dedicated inspection instrument. Also in this case, the pad 152 is located in a region close to the light-receiving surface, so that interference between the inspection instrument and the image sensor 100 is prevented. This facilitates the measurement of ball shear strength with the inspection instrument.

In a step of inspecting the image sensor 100, the pad 152 may be used as an inspection pad. Also, in this case, the pad 152 is located in a region close to the light-receiving surface, so that it is easy to establish contact between the pad 152 and a probe for inputting control signals and detecting image signals therethrough. Inspection of the image sensor 100 is thus simplified.

In a step of manufacturing the image sensor 100, the opening 151 may be formed after fabrication of the incident light transmission section 110, as will be discussed later. At the time the color filter 112 and the on-chip lens 111 are to be formed, material of the color filter 112 and other parts can be applied onto a flat surface of the semiconductor substrate 120 where the opening 151 has yet to be formed. The material of the color filter 112 and other parts can be thus made uniform in film thickness. This improves the performance of the incident light transmission section 110 and facilitates the formation thereof. Incidentally, the pad 152 is an example of the signal transmission section described in the appended claims.

The example above is not limitative of how the image sensor 100 is configured. For example, a solder ball may be formed on the surface of the pad 152 so that image signals and other data may be transmitted through the solder ball. As another example, the pad 152 may be arranged in a region ranging from the recessed section 122 formed in the semiconductor substrate 120 to the multiple insulation layers and wiring layers in the wiring section 130. That is, the pad 152 may be arranged in the region where the semiconductor substrate 120 and the wiring section 130 are formed. The size of the pad 152 may be determined up to the size of that region. The present technology may also be applied to front-illuminated image sensors. In a front-illuminated image sensor with a thick semiconductor substrate or in a front-illuminated image sensor in which the film thickness of the wiring section is enlarged due to multilayer wiring, part of the pad may be arranged in the recessed section formed in the semiconductor substrate, with the opening formed in the semiconductor substrate to permit wire bonding therethrough. This arrangement shortens the distance between the bonding surface and the pad.

[Method of Manufacturing the Image Sensor]

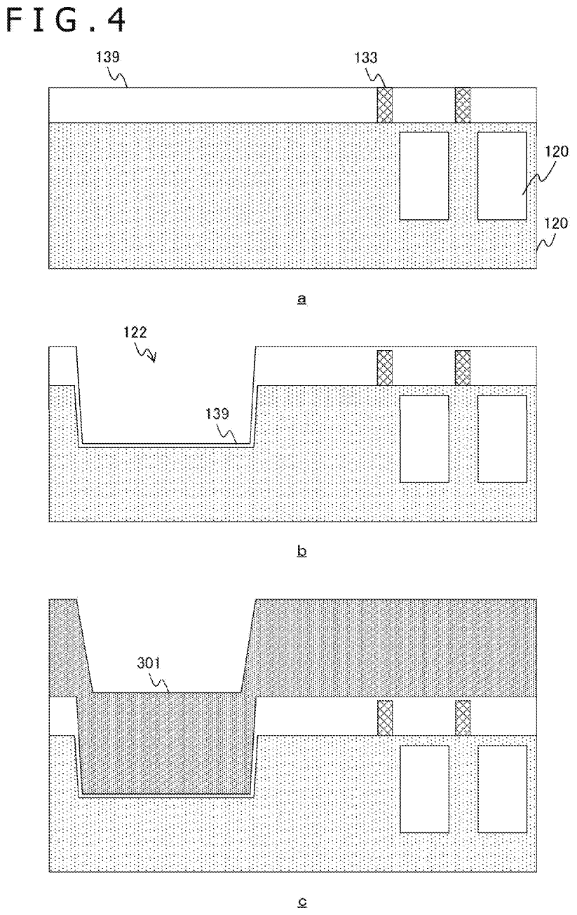

FIGS. 4 to 7 are views depicting an exemplary method of manufacturing an image sensor according to a first embodiment of the present technology. The process of manufacturing the image sensor 100 is explained below using FIGS. 4 to 7. First, a P-type well region is formed in the semiconductor substrate 120. In this well region, an N-type semiconductor region 121 and a diffusion region portion of the pixel circuit are formed. This is achieved by ion implantation, for example. A gate insulating film and a gate electrode (not depicted) are then formed, and a film of an insulating material 139 is fabricated. Silicon oxide (SiO₂) may be used as the insulating material 139, for example. Next, via plugs 133 are formed. This is achieved by forming via holes in the film of the insulating material 139 and by having the via holes filled with a metal such as tungsten (W)(Subfigure a in FIG. 4).

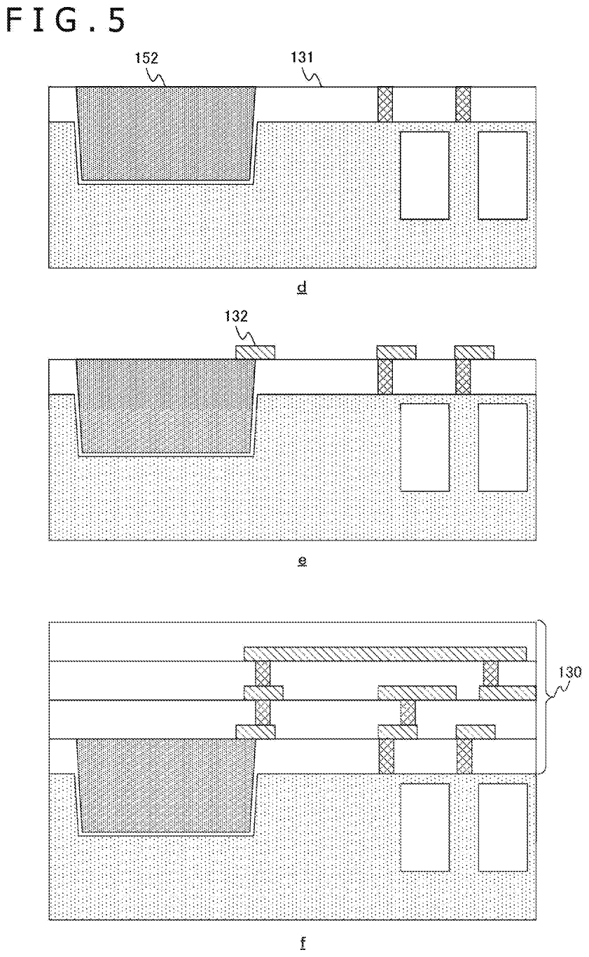

Next, dry etching is performed on the insulating material 139 and on the semiconductor substrate 120, and the recessed section 122 is formed on the semiconductor substrate 120. A thin film of the insulating material 139 is formed all over the surface (Subfigure b in FIG. 4). The thin film of the insulating material 139 insulates the semiconductor substrate 120 and the pad 152. A metallic film 301 is then formed all over the surface (Subfigure c in FIG. 4). The metallic film 301 is an Al film that serves as the material of the pad 152. The excess metallic film 301 is then removed to form the pad 152. Formation of the pad 152 will be discussed later in detail. Part of the pad 152 thus formed is arranged in the recessed section 122 fabricated in the semiconductor substrate 120 (Subfigure d in FIG. 5). This step of forming the pad 152 is an example of a step of forming the signal transmission section described in the appended claims.

Next, after a metallic film typically of Cu is formed all over the surface, the portion of the film other than the desired wiring pattern is removed by etching to form a wiring layer 132 (Subfigure e in FIG. 5). The wiring layer 132, formed in a manner partially adjacent to the pad 152 and via plug 133, is electrically connected with the pad 152 or the like. Thereafter the insulation layer 131, wiring layer 132, and via plug 133 are formed multiple times to constitute the wiring section 130 of a multilayer structure (Subfigure f in FIG. 5). In this case, the via plugs 133 formed for the second time or thereafter may be configured using Cu, for example. The insulation layer 131 formed for the second time or thereafter may be configured using TEOS (Tetra Ethyl Ortho Silicate), for example. Incidentally, a step of forming the insulation layer 131 and wiring layer 132 or the like is an example of a step of forming the wiring section described in the appended claims.

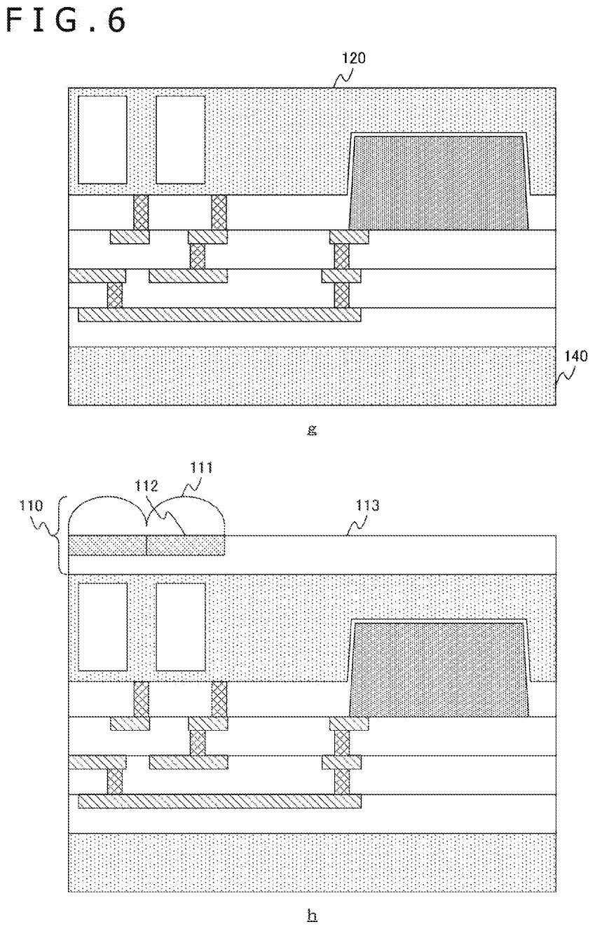

Next, the semiconductor substrate 120 is turned upside down. The support substrate 140 is bonded to the wiring section 130. This is achieved by a known method such as by application of an adhesive agent. The semiconductor substrate 120 is then thinned by polishing (Subfigure g in FIG. 6). The incident light transmission section 110 is then formed. This is accomplished by forming the protective film 113, color filter 112, and on-chip lens 111, in that order, on the polished surface of the semiconductor substrate 120 (Subfigure h in FIG. 6). The color filter 112 is formed, for example, by uniformly applying a resin material over the protective film 113 of the semiconductor substrate 120, letting the applied material harden, and having the hardened material patterned. The on-chip lens 111 is formed, for example, by also applying uniformly a resin material and having the applied material treated by a known method such as by thermal melt flow.

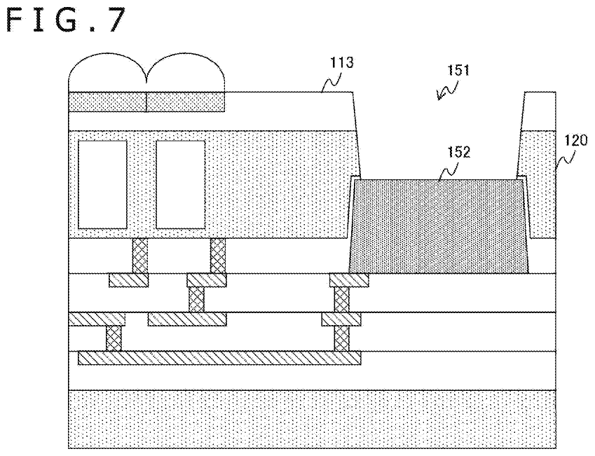

Then the opening 151 is formed in the protective film 113 and in the semiconductor substrate 120. Dry etching or the like may be used to form the opening 151 from the surface side (light-receiving surface) of the semiconductor substrate 120 up to the pad 152 (FIG. 7). A step of forming the opening 151 is an example of a step of forming the opening described in the appended claims. Thereafter, bonding onto the pad 152 is accomplished through the opening 151. The image sensor 100 is manufactured in the above-described steps.

Of the above steps of manufacturing the image sensor 100, those of forming the MOS transistors of the pixel 10 in the semiconductor substrate 120 up to forming the via plug 133 (using W)(Subfigure a in FIG. 4) are carried out at relatively high temperatures (400° C. or higher). For example, at the time of forming the diffusion layer in the semiconductor substrate 120 during MOS transistor formation, ion implantation needs to be followed by annealing. The annealing step heats the semiconductor substrate 120 up to 600° C. or thereabout. Because the above step of forming the pad 152 is performed after such a high-temperature process, the pad 152 can be fabricated without thermal constraints. Specifically, Al, which is a common material for bonding pads and has a relatively low melting point, may be adopted as the material for the pad 152.

Meanwhile, the incident light transmission section 110 is formed after the step of forming the pad 152 (Subfigure h in FIG. 6). After the incident light transmission section 110 is formed, the opening 151 leading up to the pad 152 is fabricated (FIG. 7). As discussed above, when the color filter 112 and on-chip lens 111 are to be formed, the resin material needs to be applied uniformly. This is to minimize modifications in optical characteristics. Because the incident light transmission section 110 is formed before fabrication of the opening 151, the opening 151 will not interfere with the application of the resin. This contributes to forming a uniform color filter 112 and a uniform on-chip lens 111.

[Method of Manufacturing the Signal Transmission Section]

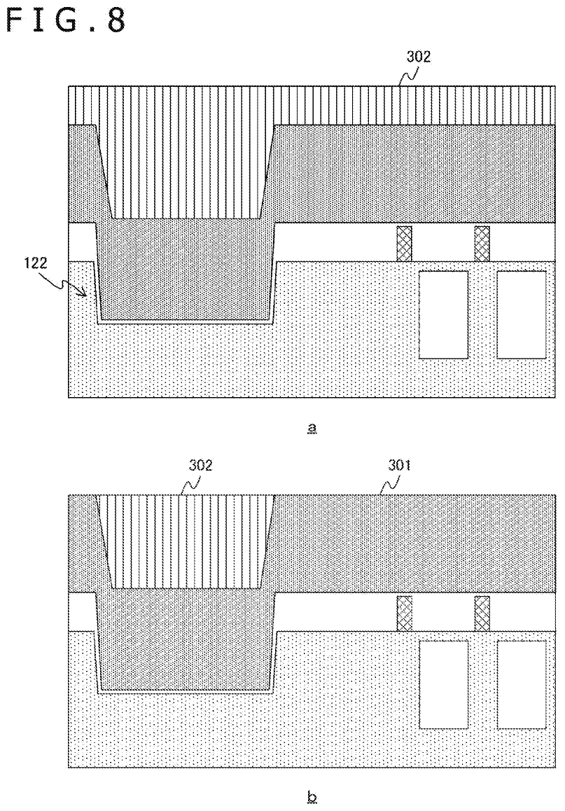

FIG. 8 is a view depicting an exemplary method of manufacturing a signal transmission section according to the first embodiment of the present technology. This drawing depicts the step of manufacturing the pad 152 constituting the signal transmission section, and gives details of the manufacturing step in Subfigure d in FIG. 5.

A resist 302 is stacked over the metallic film 301 (Subfigure a in FIG. 8) formed on the semiconductor substrate 120 in Subfigure c in FIG. 4. At this point, the resist 302 is applied in a manner forming a uniform surface shape. This makes the resist 302 in the recessed section 122 of the semiconductor substrate 120 larger in film thickness than the resist 302 in the other regions. The resist 302 is then etched to expose the metallic film 301 formed in the regions other than the recessed section 122 (Subfigure b in FIG. 8). Thereafter, the resist 302 and the metallic film 301 are etched. The etching may be performed as dry etching. In this case, either oxygen (O₂) or nitrogen (N₂) is used in combination with chlorine (Cl₂) as the gas. The gas permits etching of the resist 302 and metallic film 301 (Al) simultaneously to form the pad 152.

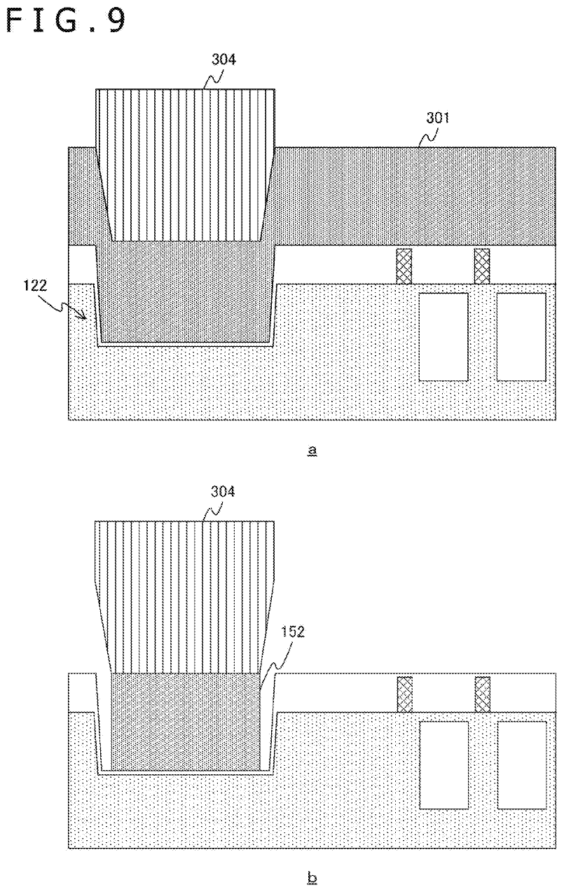

FIG. 9 is another view depicting another exemplary method of manufacturing the signal transmission section according to the first embodiment of the present technology. A resist 304 is formed over the surface of the metallic film 301 fabricated on the semiconductor substrate 120 (Subfigure a in FIG. 9). This is achieved by performing exposure and development following application of the resist and by removing the resist from the regions except from the recessed section 122 in the semiconductor substrate 120. The metallic film 301 is then etched except from the region covered with the resist 304. For this etching, dry etching may also be adopted. In this case, Cl₂ and boron trichloride (BCl₃) are used as the gas. The gas permits etching of the metallic film 301 (Al) only (Subfigure b in FIG. 9). Thereafter, the resist 304 is removed to form the pad 152.

The pad 152 may be formed alternatively by a manufacturing method other than those described with reference to FIGS. 8 and 9. For example, in the case of Subfigure c in FIG. 4, the pad 152 may be formed by polishing the metallic film 301 fabricated on the semiconductor substrate 120 so as to remove the metallic film 301 from the regions except from the recessed section 122 in the semiconductor substrate 120. Polishing of the metallic film 301 is accomplished by chemical mechanical polishing (CMP), for example.

As explained above, in the image sensor 100 according to the first embodiment of the present technology, the pad 152 is arranged between the semiconductor substrate 120 and the insulation layer 131 and is partially located in the recessed section 122 formed in the semiconductor substrate 120. Signals are then transmitted via the pad 152 by way of the opening 151 formed on the light-receiving surface of the semiconductor substrate 120, which is on the surface side of the image sensor 100. In this arrangement, the pad 152 may be made larger in film thickness while being positioned close to the surface of the image sensor 100. In a case where wire bonding is to be performed on the pad 152, the pad 152 may be formed to a desired thickness.

### 2. Second Embodiment

In the above-described first embodiment, part of the wiring layer 132 is connected to the pad 152 in a bonding section between the wiring layer 132 and the pad 152. By contrast, a second embodiment of the present technology differs from the first embodiment in that in keeping with the current flowing through the bonding section, the area of connection between the bonded parts is varied.

[Configuration of the Image Sensor]

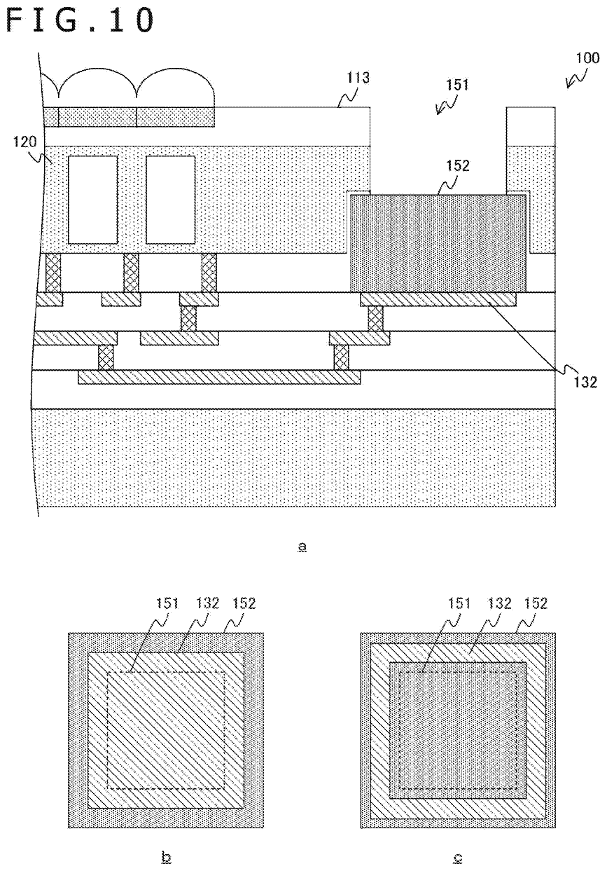

FIG. 10 is a view depicting an example of the configuration of an image sensor according to the second embodiment of the present technology. The image sensor 100 in FIG. 10 differs from the image sensor 100 discussed with reference to FIG. 3 in that the image sensor 100 in FIG. 10 has a wider area of bonding between the pad 152 and the wiring layer 132 than the image sensor 100 in FIG. 3. Subfigure a in FIG. 10 depicts a cross-section of the image sensor 100, and Subfigure b in FIG. 10 illustrates how the pad 152 and the wiring layer 132 are arranged. Subfigure b in FIG. 10 depicts what the pad 152 and the wiring layer 132 look like when viewed from the surface opposite to the light-receiving surface of the image sensor 100. Dotted lines in Subfigure b in FIG. 10 represent the opening 151.

As is evident from Subfigures a and b in FIG. 10, the wiring layer 132 is bonded to a wide area of the pad 152. This reduces the connection resistance between the wiring layer 132 and the pad 152. This arrangement may be adopted in a case where a relatively large current flows to the pad 152 from, for example, a power supply line connected therewith or where signals need to be transmitted at high speed via the pad 152. Further, the wider area of bonding between the wiring layer 132 and the pad 152 helps reduce effects of defects of connection irregularities such as bonding failures.

As with Subfigure b in FIG. 10, Subfigure c in FIG. 10 depicts how the pad 152 and the wiring layer 132 look line when viewed from the surface opposite to the light-receiving surface of the image sensor 100. In Subfigure c in FIG. 10, the wiring layer 132 is arranged around the pad 152. The position where the wiring layer 132 is arranged corresponds to a spacing between the opening 151 and the edges of the pad 152. As described above, at the time of wire bonding to the pad 152, the bonding wire is heat- and pressure-bonded to the pad 152. The impact from the heat and pressure bonding can destroy the connection section between the pad 152 and the wiring layer 132, potentially leading to lowered connection reliability such as an increase in resistance of the connection section. The effects of the impact from bonding may be reduced by arranging the wiring layer 132 between the opening 151 and the edges of the pad 152. This contributes to improving the connection reliability between the pad 152 and wiring layer 132.

The remaining configuration of the image sensor 100 is similar to that of the image sensor 100 explained in connection with the first embodiment of the present technology and thus will not be discussed further.

As explained above, in the image sensor 100 according to the second embodiment of the present technology, the area of connection between the wiring layer 132 and the pad 152 is varied depending on the state of use of the connection section. This reduces the occurrence of irregularities such as an increase in connection resistance.

### 3. Third Embodiment

In the above-described first embodiment, the wiring layer 132 is directly connected to the pad 152. By contrast, a third embodiment of the present technology differs from the first embodiment in that the wiring layer 132 is connected to the pad 152 by way of the via plug 133.

[Configuration of the Image Sensor]

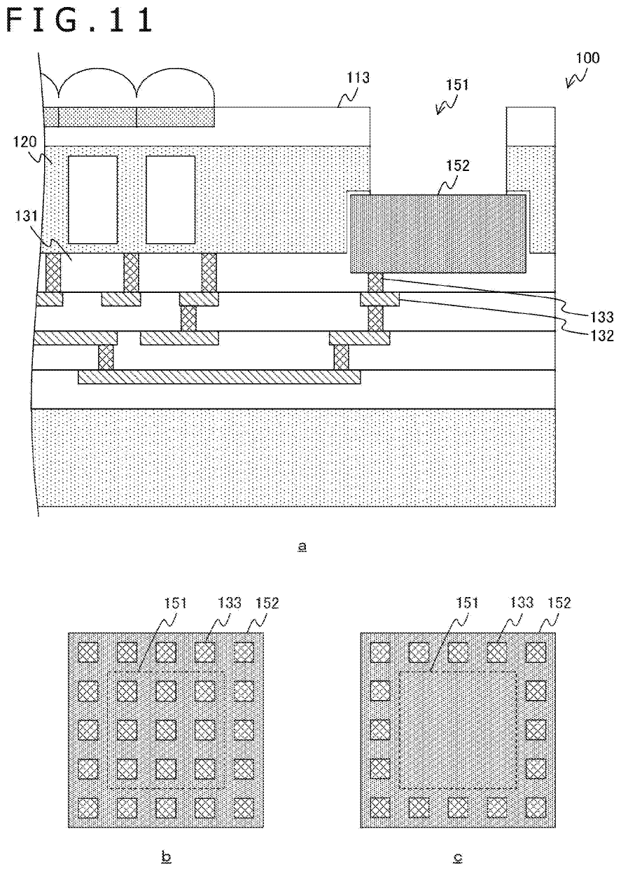

FIG. 11 is a view depicting an example of the configuration of an image sensor according to the third embodiment of the present technology. Subfigure a in FIG. 11 is a cross-sectional view of the image sensor 100. The image sensor 100 in Subfigure a in FIG. 11 is different from the image sensor 100 explained with reference to FIG. 3 in that in the image sensor 100 in FIG. 11, the wiring layer 132 and the pad 152 are connected by way of one via plug 133. In a case where the insulation layer 131 adjacent to the semiconductor substrate 120 has a relatively large film thickness or where the wiring layer 132 has a relatively small film thickness, the via plug 133 may be arranged between the wiring layer 132 and the pad 152 in a manner adjusting the spacing between the wiring layer 132 and the pad 152.

Meanwhile, Subfigures b and c in FIG. 11 depict examples in which multiple via plugs 133 are used to connect the wiring layer 132 with the pad 152. Incidentally, Subfigures b and c in FIG. 11 depicting how the pad 152 and the via plugs 133 are arranged illustrate what the pad 152 and other parts look like when viewed from the surface opposite to the light-receiving surface of the image sensor 100 as in the case of FIG. 10. In Subfigure b in FIG. 11, the via plugs 133 are arranged in a manner distributed over a wide range of the pad 152. This arrangement reduces the resistance of the connection section. In Subfigure c in FIG. 11, the via plugs 133 are arranged between the opening 151 and the edges of the pad 152. This arrangement reduces the effects of the impact from bonding and improves the connection reliability between the pad 152 and the wiring layer 132.

The remaining configuration of the image sensor 100 is similar to that of the image sensor 100 explained in connection with the first embodiment of the present technology and thus will not be discussed further.

As explained above, in the image sensor 100 according to the third embodiment of the present technology, the via plugs 133 are arranged between the wiring layer 132 and the pad 152 in a manner adjusting the spacing therebetween. This permits usage of the wiring layer 132 or the like with a desired film thickness.

### 4. Fourth Embodiment

In the above-described first embodiment, the image sensor 100 has the support substrate 140 bonded to the wiring section 130 of the semiconductor substrate 120. By contrast, a fourth embodiment of the present technology differs from the first embodiment in that the imaging apparatus is configured by bonding a semiconductor substrate having a wiring layer to the image sensor 100.

[Configuration of the Imaging Apparatus]

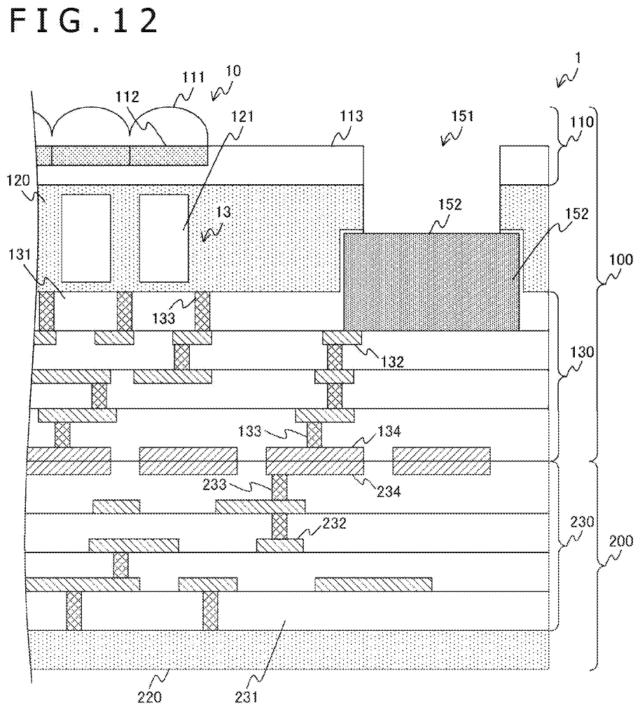

FIG. 12 is a view depicting an example of the configuration of an imaging apparatus according to the fourth embodiment of the present technology. The imaging apparatus 1 in FIG. 12 is configured by bonding the peripheral circuit chip 200 explained with reference to FIG. 1 to the image sensor 100.

The image sensor 100 in FIG. 12 is different from the image sensor 100 explained with reference to FIG. 3 in that a pad 134 is provided in the outermost of the insulation layers 131 in the wiring section 130. The pad 134 is bonded to a pad 234 of the peripheral circuit chip 200, to be discussed later, to permit transmission of image signals and other signals to and from the peripheral circuit chip 200. The signals are transmitted to the pad 134 by way of the via plug 133 and the wiring layer 132. The pad 134 may be configured using a metal such as Cu.

The peripheral circuit chip 200 in FIG. 12 includes a semiconductor substrate 220 and a wiring section 230. The semiconductor substrate 220 is a semiconductor substrate in which the semiconductor portions of the vertical drive section 2, column signal processing section 3, and control section 4 explained with reference to FIG. 1 are formed. The wiring section 230 is configured with a wiring layer 232 for transmitting the signals of the semiconductor substrate 220 and with insulation layers 231. Further, a pad 234 typically constituted by Cu or the like is arranged in the outermost of the insulation layers 231 in the wiring section 230. A via plug 233 may be used to interconnect the semiconductor substrate 120, wiring layers 232, and pad 234.

The pads 134 and 234, when connected with each other, transmit signals between the image sensor 100 and the peripheral circuit chip 200. Specifically, the pads 134 and 234 are positioned in contact with each other. The wiring section 130 of the image sensor 100 is bonded face-to-face to the wiring section 230 of the peripheral circuit chip 200. In this case, the image sensor 100 and the peripheral circuit chip 200 are heat- and pressure-bonded to each other to provide electric connection between the pads 134 and 234 while ensuring mechanical bonding strength therebetween. Because the pads 134 and 234 may be formed by a method similar to that of fabricating the wiring layers 132 and 232, the pads 134 and 234 may be positioned where desired on the surface of the wiring sections 130 and 230. This shortens the wiring distance between the image sensor 100 and the peripheral circuit chip 200.

In the image sensor 100 in FIG. 12, the pad 152 transmits the image signal processed by the peripheral circuit chip 200. Signals are transmitted to the pad 152 via the wiring layers 132 and 232 and by way of the pads 134 and 234. The method of transmitting signals by use of the pads 134 and 234 may be applied to transmission of the image signal from the image sensor 100 to the peripheral circuit chip 200 and to transmission of the control signal from the peripheral circuit chip 200 to the image sensor 100. Incidentally, the pads 134 and 234 are an example of the second signal transmission section described in the appended claims.

The remaining configuration of the image sensor 100 is similar to that of the image sensor 100 explained in connection with the first embodiment of the present technology and thus will not be discussed further.

As explained above, the image sensor 100 according to the fourth embodiment of the present technology is bonded to the peripheral circuit chip 200 to configure the imaging apparatus 1. This makes the imaging apparatus 1 smaller in size. In this case, the signal transmission path is shortened by the pads 134 and 234 transmitting signals between the image sensor 100 and the peripheral circuit chip 200.

### 5. Fifth Embodiment

The imaging apparatus 1 according to the above-described fourth embodiment is characterized by the pads 134 and 234 transmitting signals between the image sensor 100 and the peripheral circuit chip 200. By contrast, an imaging apparatus 1 according to a fifth embodiment of the present technology differs from the fourth embodiment in that via plugs penetrating the semiconductor substrate 120 transmit signals.

[Configuration of the Imaging Apparatus]

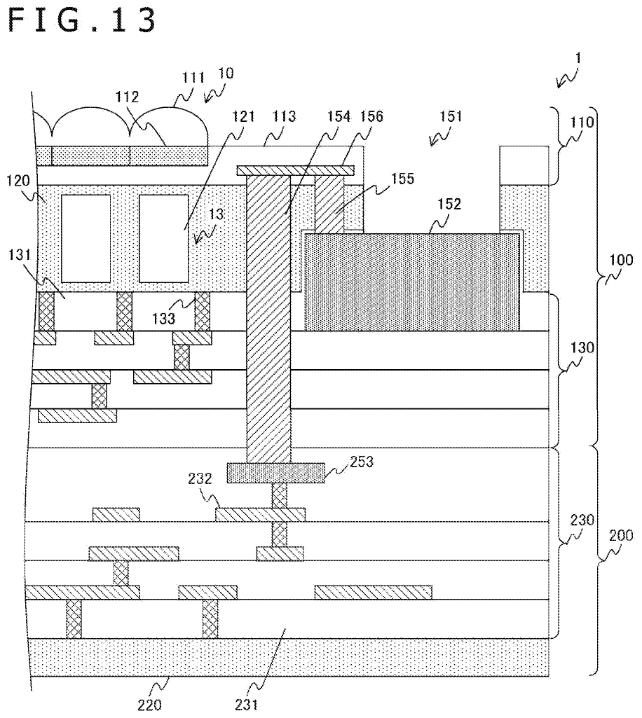

FIG. 13 is a view depicting an example of the configuration of an imaging apparatus according to the fifth embodiment of the present technology. The imaging apparatus 1 in FIG. 13 is different from the imaging apparatus 1 explained with reference to FIG. 12 in that via plugs 154 and 155 are provided to replace the pads 134 and 234. The via plugs 154 and 155 are formed in a manner penetrating the semiconductor substrate 120. Via plugs of this type are referred to as TSVs (Through Silicon Via). The via plug 154 is a TSV that penetrates the semiconductor substrate 120 and the wiring section 130 to reach the peripheral circuit chip 200. Specifically, the via plug 154 is formed between a pad 253 fabricated in the outermost of the insulation layers 231 in the wiring section 230 of the peripheral circuit chip 200 on the one hand, and a wiring layer 156 formed in the protective film 113 of the image sensor 100 on the other hand, the via plug 154 transmitting signals therebetween. The via plug 155 formed between the wiring layer 156 and the pad 152 transmits signals in a manner similar to that of the via plug 154.

In this case, the image signal processed by the peripheral circuit chip 200 is transmitted through the pad 253, via plug 154, wiring layer 156, via plug 155, and pad 152, in that order. The via plugs 154 and 155 are formed by bonding the image sensor 100 and the peripheral circuit chip 200 together before fabricating via holes typically in the semiconductor substrate 120 and by fabricating an insulation film over the inner surface of the via holes before filling the via holes with a metal such as Cu. The pad 253 may be configured with a metal such as Al or Cu as in the case of the pad 152. The metal used to fill the via holes permits connection and thereby improves the connection reliability. Because the image sensor 100 and the peripheral circuit chip 200 are bonded together before fabrication of the via plug 155, the bonding between the image sensor 100 and the peripheral circuit chip 200 is made easy.

The TSVs such as the via plug 154 may also be used for transmission of signals (image signals and control signals) between the image sensor 100 and the peripheral circuit chip 200. Incidentally, the via plug 154 is an example of the second signal transmission section described in the appended claims.

[Arrangement of the Via Plug]

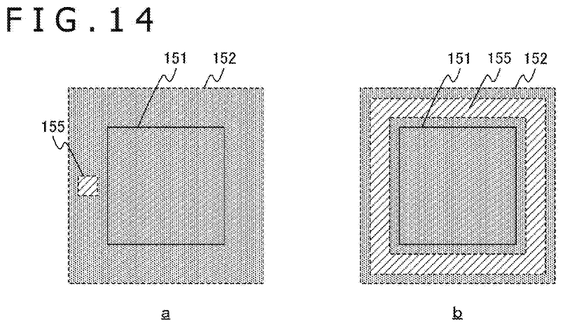

FIG. 14 is a view depicting an example of the configuration of a via plug according to a fifth embodiment of the present technology. FIG. 14 illustrates how the pad 152 and the via plug 155 are arranged. Contrary to FIGS. 10 and 11, FIG. 14 depicts the arrangement as viewed from the light-receiving surface. Subfigure a in FIG. 14 illustrates how the pad 152 and the via plug 155 are arranged in the imaging apparatus 1 explained with reference to FIG. 13, and gives an example in which the via plug 155 has a relatively small area. The via plug 154 and the wiring layer 156 are not depicted in the drawing. By contrast, Subfigure b in FIG. 14 depicts an example in which a ring-like via plug 155 is arranged to have a relatively large area. The area of the via plug 155 may thus be determined in consideration of connection resistance. In any case, the via plug 155 is located between the opening 151 and the edges of the pad 152.

The remaining configuration of the imaging apparatus 1 is similar to that of the imaging apparatus 1 explained in connection with the fourth embodiment of the present technology and thus will not be discussed further.

[Modifications]

In the imaging apparatus 1 according to the above-described fifth embodiment, signal transmission between the chips is accomplished by use of multiple TSVs such as the via plugs 154 and 155. Alternatively, a single via plug may be used to permit the transmission of signals between the chips.

[Other Configurations of the Imaging Apparatus]

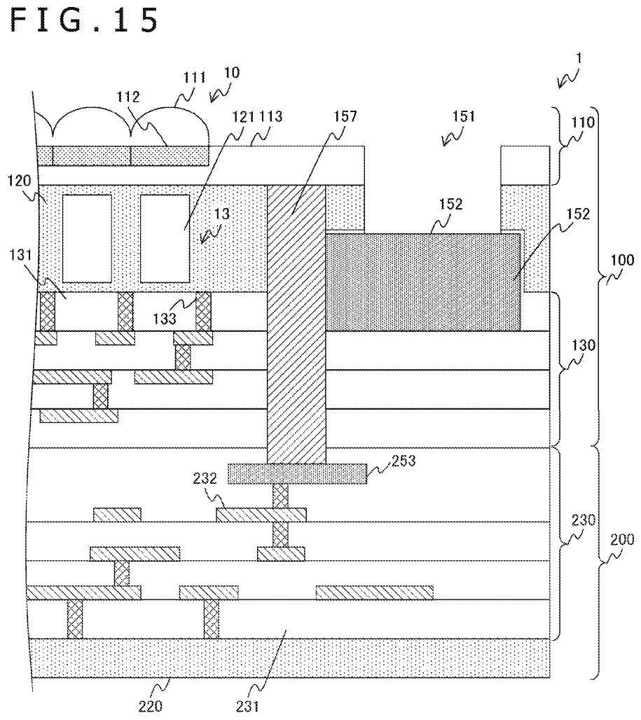

FIG. 15 is a view depicting an example of the configuration of an imaging apparatus according to a modification of the fifth embodiment of the present technology. The imaging apparatus 1 in FIG. 15 differs from the imaging apparatus 1 explained with reference to FIG. 13 in that a via plug 157 is provided to replace the via plugs 154 and 155 and the wiring layer 156.

The via plug 157 is a TSV that is electrically connectable also with the side surface of a metal or the like filling the via hole. In FIG. 15, bringing the side surface of the via plug 157 into contact with the pad 152 establishes connection therebetween. The connection permits transmission of signals.

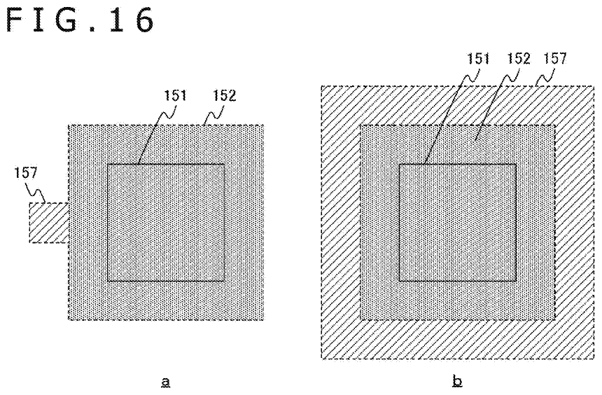

FIG. 16 is a view depicting an example of the configuration of a via plug according to a modification of the fifth embodiment of the present technology. FIG. 16 illustrates what the arrangement of the pad 152 and the via plug 157 looks like when viewed from the light-receiving surface as in the case of FIG. 14. Subfigure a in FIG. 16 depicts how the pad 152 and the via plug 157 are arranged in the imaging apparatus 1 explained with reference to FIG. 15. The via plug 157 having a rectangular cross-section is arranged in such a manner that one of the four sides of the via plug 157 comes adjacent to the pad 152. Subfigure b in FIG. 16, on the other hand, depicts an example in which the via plug 157 is arranged around the pad 152. This is an example of how the contact area between the via plug 157 and the pad 152 is enlarged. In Subfigure b of FIG. 16, the connection resistance between the via plug 157 and the pad 152 is reduced.

The remaining configuration of the imaging apparatus 1 is similar to that of the imaging apparatus 1 explained in connection with the fifth embodiment of the present technology and thus will not be discussed further.

As explained above, in the imaging apparatus 1 according to the above-described fifth embodiment of the present technology, the TSVs such as the via plug 154 are used for transmitting signals between the image sensor 100 and the peripheral circuit chip 200. This improves the connection reliability between the image sensor 100 and the peripheral circuit chip 200.

Lastly, the above-described embodiments of the present technology are only examples and are not limitative of this technology. It is evident that various modifications, variations, and alternatives other than the above embodiments may include the present technology so far as they are within the technical scope thereof.

The present disclosure may be implemented preferably in the following configurations:

(1)

An imaging apparatus including:

a semiconductor substrate on which is formed a photoelectric conversion section configured to generate an image signal corresponding to emitted light; a wiring section configured to have an insulation layer and a wiring layer stacked one on top of the other on a surface different from a light-receiving surface of the semiconductor substrate to which the light is emitted, the wiring layer transmitting the generated image signal; and

a signal transmission section configured to be formed between a recessed section formed on the surface different from the light-receiving surface of the semiconductor substrate and the wiring section, the signal transmission section being further arranged partially in the recessed section, and further transmitting the image signal transmitted by the wiring layer through an opening formed from the light-receiving surface of the semiconductor substrate toward the recessed section.

(2)

The imaging apparatus according to (1), further including:

an incident light transmission section configured to be arranged adjacent to the light-receiving surface and to transmit the emitted light to the photoelectric conversion section, in which

the signal transmission section transmits the image signal through the opening formed after fabrication of the incident light transmission section.

(3)

The imaging apparatus according to (1) or (2), in which

the signal transmission section is configured with a pad.

(4)

The imaging apparatus according to any one of (1) to (3), further including:

a via plug configured to be arranged between the wiring layer and the signal transmission section and to transmit the image signal.

(5)

The imaging apparatus according to any one of (1) to (4), further including:

a second semiconductor substrate on which is formed a processing circuit configured to process an image signal transmitted by the wiring layer;

a second wiring section configured to have a second insulation layer and a second wiring layer stacked one on top of the other on the second semiconductor substrate, the second wiring layer transmitting the processed image signal; and

a second signal transmission section configured to transmit to the signal transmission section the processed image signal transmitted by the second wiring layer;

in which the signal transmission section transmits an image signal processed by the processing circuit and transmitted by the second signal transmission section.

(6)

The imaging apparatus according to (5), in which

the second signal transmission section is configured with a pad arranged in the wiring section and with a pad arranged in the second wiring section.

(7)

The imaging apparatus according to (5), in which

the second signal transmission section is configured with a via plug arranged in a manner penetrating the wiring section and the semiconductor substrate.

(8)

A method of manufacturing an imaging apparatus, the method including the steps of:

forming a signal transmission section partially in a recessed section formed on a surface different from a light-receiving surface of a semiconductor substrate on which is formed a photoelectric conversion section for generating an image signal corresponding to light emitted to the light-receiving surface, the signal transmission section being configured to transmit the image signal;

forming a wiring section with a wiring layer adjacent to the surface different from the light-receiving surface of the semiconductor substrate and adjacent to the signal transmission section, the wiring layer being configured to transmit the image signal generated by the photoelectric conversion section to the signal transmission section; and

forming an opening from the light-receiving surface of the semiconductor substrate toward the recessed section, the opening being configured to permit signal transmission from the signal transmission section.

### REFERENCE SIGNS LIST

1 Imaging apparatus
2 Vertical drive section
3 Column signal processing section
4 Control section
10 Pixel
13 Photoelectric conversion section
14 Charge retention section
100 Image sensor
110 Incident light transmission section
111 On-chip lens
112 Color filter
113 Protective film
120 Semiconductor substrate
122, 135 Recessed section
130, 156, 230 Wiring section
131, 231 Insulation layer
132, 232 Wiring layer
133, 154, 155, 157, 233 Via plug
134, 152, 234, 253 Pad
140 Support substrate
151 Opening
153 Bonding wire
200 Peripheral circuit chip
220 Semiconductor substrate

What is claimed is:

1. An imaging apparatus comprising:
a semiconductor substrate on which is formed a photoelectric conversion section configured to generate an image signal corresponding to emitted light;
a wiring section configured to have an insulation layer and a wiring layer stacked one on top of the other on a surface different from a light-receiving surface of the semiconductor substrate to which the light is emitted, the wiring layer transmitting the generated image signal; and
a signal transmission section configured to be formed between a recessed section formed on the surface different from the light-receiving surface of the semiconductor substrate and the wiring section, the signal transmission section being further arranged partially in the recessed section, and further transmitting the image signal transmitted by the wiring layer through an opening formed from the light-receiving surface of the semiconductor substrate toward the recessed section.

2. The imaging apparatus according to claim 1, further comprising:
an incident light transmission section configured to be arranged adjacent to the light-receiving surface and to transmit the emitted light to the photoelectric conversion section, wherein
the signal transmission section transmits the image signal through the opening formed after fabrication of the incident light transmission section.

3. The imaging apparatus according to claim 1, wherein
the signal transmission section is configured with a pad.

4. The imaging apparatus according to claim 1, further comprising:
a via plug configured to be arranged between the wiring layer and the signal transmission section and to transmit the image signal.

5. The imaging apparatus according to claim 1, further comprising:
a second semiconductor substrate on which is formed a processing circuit configured to process an image signal transmitted by the wiring layer;
a second wiring section configured to have a second insulation layer and a second wiring layer stacked one on top of the other on the second semiconductor substrate, the second wiring layer transmitting the processed image signal; and
a second signal transmission section configured to transmit to the signal transmission section the processed image signal transmitted by the second wiring layer, wherein
the signal transmission section transmits an image signal processed by the processing circuit and transmitted by the second signal transmission section.

6. The imaging apparatus according to claim 5, wherein
the second signal transmission section is configured with a pad arranged in the wiring section and with a pad arranged in the second wiring section.

7. The imaging apparatus according to claim 5, wherein
the second signal transmission section is configured with a via plug arranged in a manner penetrating the wiring section and the semiconductor substrate.

8. A method of manufacturing an imaging apparatus, the method comprising the steps of:
forming a signal transmission section partially in a recessed section formed on a surface different from a light-receiving surface of a semiconductor substrate on which is formed a photoelectric conversion section for generating an image signal corresponding to light emitted to the light-receiving surface, the signal transmission section being configured to transmit the image signal;
forming a wiring section with a wiring layer adjacent to the surface different from the light-receiving surface of the semiconductor substrate and adjacent to the signal transmission section, the wiring layer being configured to transmit the image signal generated by the photoelectric conversion section to the signal transmission section; and
forming an opening from the light-receiving surface of the semiconductor substrate toward the recessed section, the opening being configured to permit signal transmission from the signal transmission section.
